(19) United States
(12) Patent Application Publication
(10) Pub. No.: US 2026/0126683 A1
(43) Pub. Date: May 7, 2026

(54) DISPLAY DEVICE

(71) Applicant: Shanghai Tianma Micro-Electronics Co., Ltd., Shanghai (CN)

(72) Inventor: Tomoya OGI, Kawasaki (JP)

(73) Assignee: Shanghai Tianma Micro-Electronics Co., Ltd., Shanghai (CN)

(21) Appl. No.: 19/377,433

(22) Filed: Nov. 3, 2025

(30) Foreign Application Priority Data
Nov. 6, 2024 (JP) 2024-194326
Jul. 9, 2025 (JP) 2025-115985

(51) Int. Cl. G02F 1/1333; H10K 59/127; H10K 59/40; H10K 59/80; H10K 77/10

(52) U.S. Cl. CPC G02F 1/133305; G02F 1/133308; G02F 1/133368; G02F 1/13338; H10K 59/127; H10K 59/40; H10K 59/872; H10K 77/111

(57) ABSTRACT

A display device includes a display panel, a flexible substrate that connects to the display panel and connects the display panel to the outside, and a housing that accommodates the display panel and has an opening in a side plate through which the flexible substrate passes. The display device further includes a cover and a waterproof film. The cover is disposed on a display surface side of the display panel and adhered to the housing. The waterproof film is affixed to a main surface of the cover on a display panel side thereof, a side plate of the housing having the opening, and bottom surface of the housing, and covering a gap, including the opening, between the cover and the side plate of the housing having the opening, with the flexible substrate passing through the opening.

### CROSS-REFERENCE TO RELATED APPLICATIONS

The present disclosure claims the benefits of Japanese Patent Application No. 2024-194326, filed on Nov. 6, 2024, and Japanese Patent Application No. 2025-115985, filed on Jul. 9, 2025, the entire disclosure of which are incorporated by reference herein.

### FIELD OF THE INVENTION

The present disclosure relates generally to a display device.

### BACKGROUND OF THE INVENTION

Display devices mounted on vehicles, laptop-type computers, and the like, are required to be waterproof. For example, even when drinking water is spilled onto a display device installed in a vehicle, the display device is expected not to be damaged by the drinking water.

A known approach involves providing a display device with a waterproof sheet. For example, Japanese U.S. Pat. No. 5,222,987 discloses a display device including a display panel, a frame member, and a waterproof sheet. The display panel may be, a liquid crystal display panel, an organic electro-luminescence (EL) display panel, or the like. The frame member supports the outer peripheral portion of the display surface of the display panel. The waterproof sheet is affixed to a side of the display panel to which the circuit board is connected, and extends along a surface of the frame member facing the display panel between the display panel and the frame member.

In Japanese U.S. Pat. No. 5,222,987, when moisture enters the frame member through a gap between the display panel and the frame member, moisture accumulates between the waterproof sheet and the frame member. This prevents the circuit board from corroding due to moisture.

However, this requires the frame member that supports the outer peripheral portion of the display surface of the display panel, and thus the feature of Japanese U.S. Pat. No. 5,222,987 cannot be applied to a display device not including a frame member. Furthermore, as moisture accumulates between the waterproof sheet and the frame member, the waterproof performance of the display device disclosed in Japanese U.S. Pat. No. 5,222,987 is insufficient.

### SUMMARY OF THE INVENTION

A display device according to a first aspect of the present disclosure includes:
a display panel;
a flexible substrate that connects to the display panel and connects the display panel to an outside;
a housing that accommodates the display panel and has an opening in a side plate through which the flexible substrate passes;
a cover that is disposed on a display surface side of the display panel and adhered to the housing; and
a waterproof film affixed to a main surface of the cover on a display panel side thereof, the side plate of the housing having the opening, and a bottom surface of the housing, and covering a gap, including the opening, between the cover and the side plate of the housing having the opening, with the flexible substrate passing through the opening.

A display device according to a second aspect of the present disclosure includes:
a display panel;
a first flexible substrate that connects to the display panel and connect the display panel to an outside;
a housing that accommodates the display panel and has an opening in a side plate through which the first flexible substrate passes;
a touch panel that is disposed on a display surface side of the display panel and adhered to the housing;
a second flexible substrate that connects to a frame region of the touch panel and connects the touch panel to the outside;
a cover that covers the touch panel and is adhered to the touch panel;
a first waterproof film that is affixed to a main surface of the cover on a display panel side thereof, the side plate of the housing having the opening, and a bottom surface of the housing, and covers a gap, including the opening, between the cover and the side plate of the housing having the opening, with the first flexible substrate passing through the opening; and
a second waterproof film that is affixed to the main surface of the cover on the display panel side, the side plate of the housing, and the bottom surface of the housing, and covering a gap between the cover and the frame region of the touch panel to which the second flexible substrate is connected.

A display device according to a third aspect of the present disclosure includes:
a display panel;
a first flexible substrate that connects to the display panel and connect the display panel to an outside;
a housing that accommodates the display panel and has an opening in a side plate through which the first flexible substrate passes;
a touch panel that is disposed on a display surface side of the display panel and adhered to the housing;
a second flexible substrate that connects to a frame region of the touch panel and connects the touch panel to the outside;
a cover that covers the touch panel and is adhered to the touch panel;
a first waterproof film that is affixed to a main surface of the touch panel on a display panel side thereof, the side plate of the housing having the opening, and a bottom surface of the housing, and covers a gap, including the opening, between the touch panel and the side plate of the housing having the opening, with the first flexible substrate passing through the opening; and
a second waterproof film that is affixed to the main surface of the cover on the display panel side, the side plate of the housing, and the bottom surface of the housing, and covering a gap between the cover and the frame region of the touch panel to which the second flexible substrate is connected.

It is to be understood that both the foregoing general description and the following detailed description are exemplary and explanatory and are not restrictive of this disclosure.

### BRIEF DESCRIPTION OF DRAWINGS

FIG. 1 is a plan view illustrating a display device according to Embodiment 1;

FIG. 2 is a cross-sectional view of the display device illustrated in FIG. 1, taken along line A-A;

FIG. 3 is a plan view illustrating a liquid crystal display panel according to Embodiment 1;

FIG. 4 is a cross-sectional view of the liquid crystal display panel illustrated in FIG. 3, taken along line B-B;

FIG. 5 is a cross-sectional view illustrating a flexible substrate and a housing according to Embodiment 1;

FIG. 6 is a plan view illustrating the housing according to Embodiment 1;

FIG. 7 is a perspective view illustrating a side plate and an opening of the housing according to Embodiment 1;

FIG. 8 is a perspective view illustrating the flexible substrate and a side plate and a bottom surface of the housing according to Embodiment 1;

FIG. 9 is a side view illustrating a waterproof film and the side plate according to Embodiment 1;

FIG. 10 is a cross-sectional view of the waterproof film and the side plate illustrated in FIG. 9, taken along C-C;

FIG. 11 is a cross-sectional view of the waterproof film and the side plate illustrated in FIG. 9, taken along D-d;

FIG. 12 is a perspective view illustrating a cover, the waterproof film, and the side plate and the bottom surface of the housing according to Embodiment 1;

FIG. 13 is a flowchart illustrating a manufacturing method for a display device according to Embodiment 1;

FIG. 14 is a plan view illustrating a waterproof film according to Embodiment 2;

FIG. 15 is a schematic diagram illustrating a waterproof film, a side plate, and an adhesive member according to Embodiment 2;

FIG. 16 is a side view illustrating the waterproof film and side plate according to Embodiment 2;

FIG. 17 is a plan view illustrating a display device according to Embodiment 3;

FIG. 18 is a cross-sectional view of the display device illustrated in FIG. 17, taken along line E-E;

FIG. 19 is a plan view illustrating a touch panel according to Embodiment 3;

FIG. 20 is a cross-sectional view of the display device illustrated in FIG. 17, taken along line F-F;

FIG. 21 is a side view illustrating a first waterproof film and a side plate according to Embodiment 3;

FIG. 22 is a side view illustrating a second waterproof film and a side plate according to Embodiment 3;

FIG. 23 is a cross-sectional view illustrating a display device according to Embodiment 4;

FIG. 24 is a side view illustrating a first waterproof film and a side plate according to Embodiment 4;

FIG. 25 is a cross-sectional view illustrating a waterproof film and a side plate according to Embodiment 5;

FIG. 26 is a cross-sectional view illustrating the waterproof film and the side plate

### According to Embodiment 5; and

FIG. 27 is a cross-sectional view illustrating a display device according to a modified example.

### DETAILED DESCRIPTION OF THE INVENTION

A display device according to various embodiments is described below with reference to the drawings.

### Embodiment 1

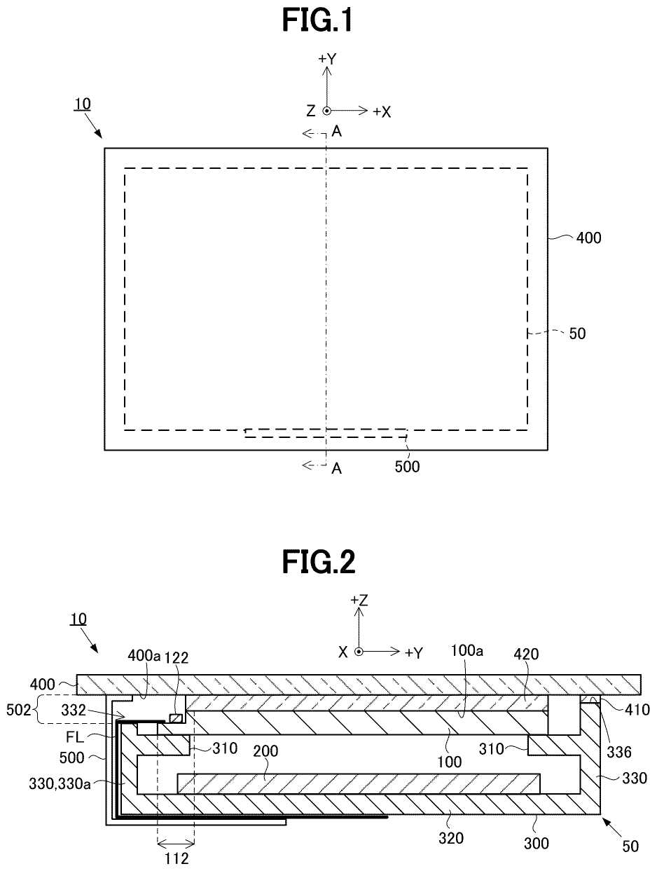

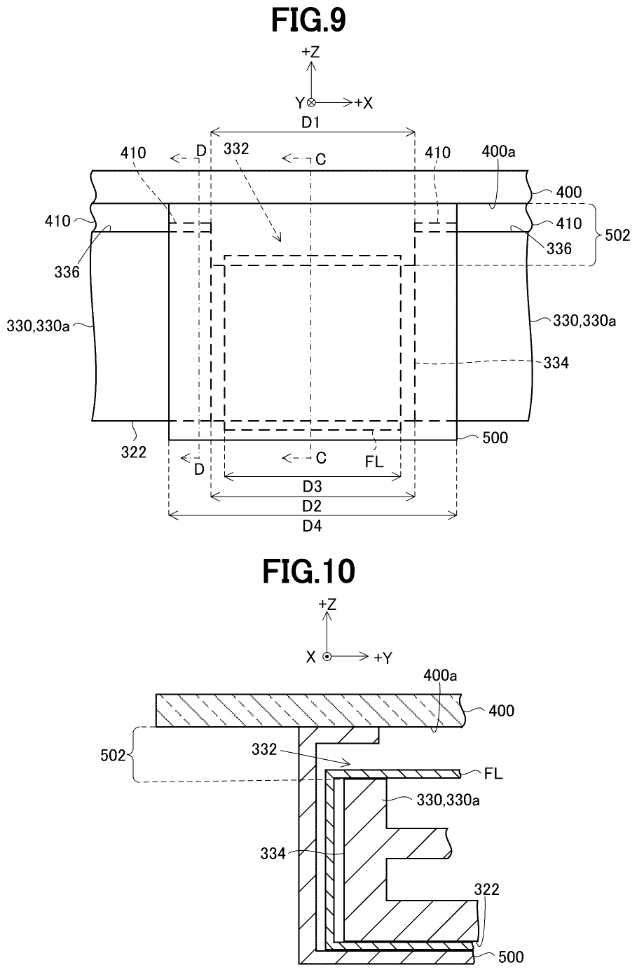

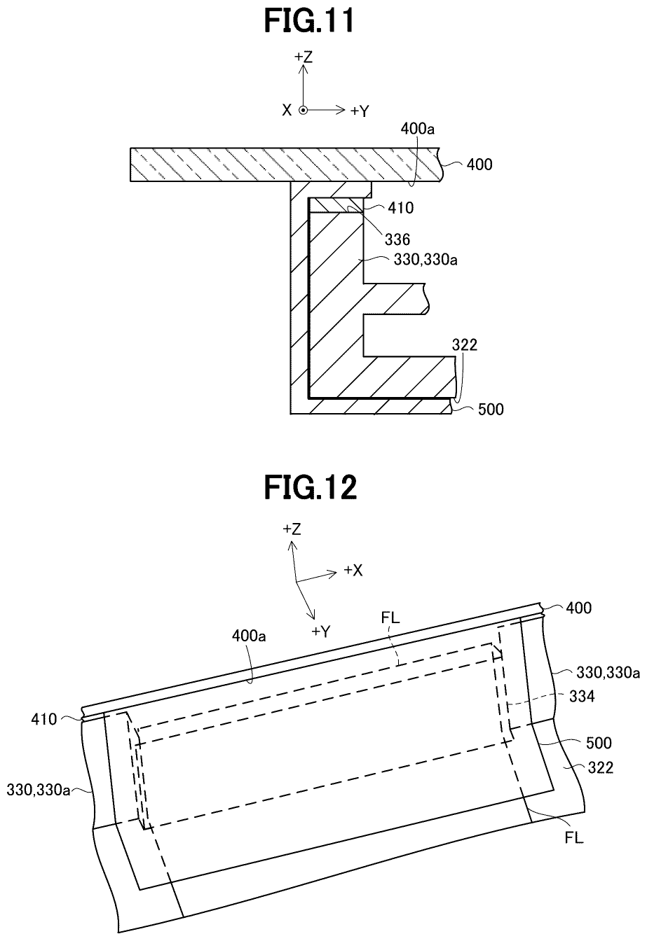

A display device 10 according to the present embodiment is described while referencing FIGS. 1 to 13. In one example, the display device 10 is mounted on a vehicle.

The display device 10 includes a display unit 50, a cover 400, and a waterproof film 500, as illustrated in FIG. 1. The display unit 50 displays characters, images, and the like. The cover 400 protects the display unit 50. The waterproof film 500 covers a gap 502 between the cover 400 and a side plate 330a of a housing 300 of the display unit 50, which are described later. The longitudinal direction of the display device 10 in FIG. 1 (the right direction on the paper) is described herein as a +X direction, the transverse direction (the up direction on the paper) as a +Y direction, and the direction perpendicular to the +X and +Y directions (the front direction on the paper, user direction) as a +Z direction.

The display unit 50 includes a liquid crystal display panel 100, a flexible substrate FL, a backlight 200, and the housing 300, as illustrated in FIG. 2. The liquid crystal display panel 100 displays text, images, and the like. The flexible substrate FL connects the liquid crystal display panel 100 to the outside. The backlight 200 is a light source for the liquid crystal display panel 100. The housing 300 accommodates the liquid crystal display panel 100 and the backlight 200. In FIG. 2, for ease of understanding, the flexible substrate FL is depicted with a solid line, and hatching for the waterproof film 500 is omitted. In the subsequent figures, the flexible substrate FL, the waterproof film 500, and the like may be depicted with solid or dashed lines, and hatching may be omitted.

The liquid crystal display panel 100 of the display unit 50 is, for example, a known transmissive horizontal electric field type liquid crystal display panel. The liquid crystal display panel 100 is active matrix driven by thin film transistors (TFT). The liquid crystal display panel 100 displays characters, images, and the like by modulating light from the backlight 200.

The liquid crystal display panel 100 includes a display region 111 and a frame region 112. The display region 111 is a region in which pixels are arranged in a matrix, and characters, images, and the like can be displayed. The frame region 112 is a region in which wiring, driver integrated circuit (IC) 122, and the like are disposed. The frame region 112 surrounds the display region 111.

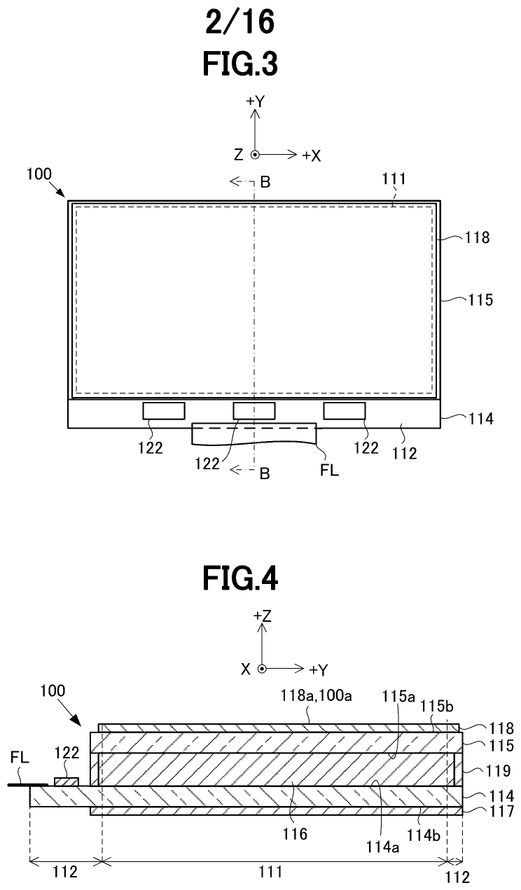

The liquid crystal display panel 100 includes a TFT substrate 114, a counter substrate 115, a liquid crystal 116, a first polarizing plate 117, a second polarizing plate 118, and a driver IC 122, as illustrated in FIGS. 3 and 4. The TFT substrate 114 and the counter substrate 115 sandwich the liquid crystal 116. The first polarizing plate 117 is provided on the TFT substrate 114, and the second polarizing plate 118 is provided on the counter substrate 115. The driver IC 122 is mounted on the frame region 112.

The TFT substrate 114 is, for example, a glass substrate. The TFT substrate 114 is positioned on the −Z side. TFTs for selecting the pixels, gate wiring, data wiring, common electrodes, pixel electrodes, an alignment film for aligning the liquid crystal 116, and the like (none of which are illustrated) are provided on a main surface 114a of the TFT substrate 114 on the liquid crystal 116 side. The first polarizing plate 117 is provided on a main surface 114b of the TFT substrate 114 opposite to the main surface 114a thereof.

The counter substrate 115 is positioned on the +Z side, and opposes the TFT substrate 114. The counter substrate 115 is adhered to the TFT substrate 114 by a seal material 119. The counter substrate 115 is, for example, a glass substrate. A color filter, a black matrix, an alignment film for aligning the liquid crystal 116, and the like (none of which is illustrated) are provided on a main surface 115a of the counter substrate 115 on the liquid crystal 116 side. The second polarizing plate 118 is provided on a main surface 115b of the counter substrate 115 opposite to the main surface 115a thereof.

The liquid crystal 116 is sandwiched by the TFT substrate 114 and the counter substrate 115. The liquid crystal 116 is, for example, a positive nematic liquid crystal. The liquid crystal 116 is initially aligned, by the alignment film, in a direction parallel to the main surface 114a of the TFT substrate 114. Additionally, in response to applied voltage, the liquid crystal 116 rotates in a plane parallel to the main surface 114a of the TFT substrate 114.

The first polarizing plate 117 is provided on the main surface 114b of the TFT substrate 114, and the second polarizing plate 118 is provided on the main surface 115b of the counter substrate 115. One transmittance axis of the transmittance axes of the first polarizing plate 117 and the second polarizing plate 118 is arranged parallel to the initial alignment direction of the liquid crystal 116, and the transmission axis of the first polarizing plate 117 is orthogonal to the transmittance axis of the second polarizing plate 118. In the present embodiment, a main surface 118a on the +Z side of the second polarizing plate 118 corresponds to a display surface 100a of the liquid crystal display panel 100.

The driver IC 122 supplies a signal to gate wiring (gate electrodes of TFTs) and data wiring (source electrodes of TFTs) based on signals supplied from the outside The driver IC 122 is mounted in the frame region 112 located on the −Y side. The driver IC 122 is connected via the flexible substrate FL to the outside. Here, the “outside” refers to a component other than the liquid crystal display panel 100, such as a drive circuit, a controller, a device, and the like.

The flexible substrate FL of the display unit 50 connects to the liquid crystal display panel 100 (driver IC 122) and connects the liquid crystal display panel 100 to the outside. The flexible substrate FL connects to the liquid crystal display panel 100 (driver IC 122) at an end portion of the frame region 112 located on the −Y side via unillustrated wiring.

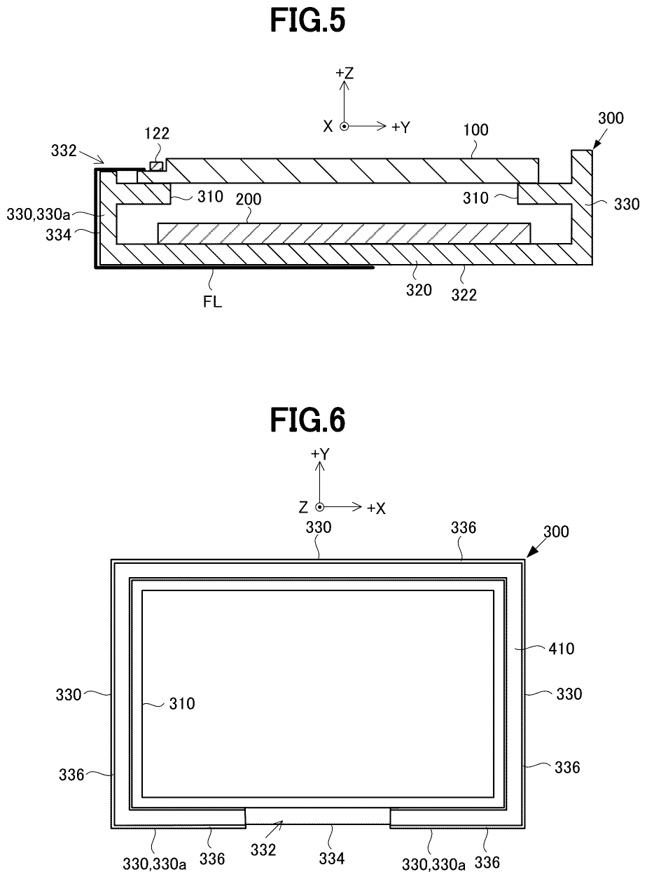

As illustrated in FIG. 5, the flexible substrate FL is led out from the end portion of the frame region 112 of the liquid crystal display panel 100 on the −Y side through an opening 332 of the housing 300 toward the outside of the housing 300. The flexible substrate FL led out from the opening 332 extends through a groove 334 of the side plate 330a of the housing 300 to a bottom surface 322 of the housing 300, as described later. In the present embodiment, the flexible substrate FL is fixed to the bottom surface 322 of the housing 300 by the unillustrated adhesive member.

The backlight 200 of the display unit 50 is disposed on the rear side (−Z side) of the liquid crystal display panel 100, as illustrated in FIG. 2. The backlight 200 emits white light toward the liquid crystal display panel 100. The backlight 200 includes a white light emitting diode (LED) element, a reflecting sheet, a diffusing sheet, a light guide plate, a lighting circuit, and the like (none of which are illustrated). The light guide plate is formed of, for example, a light-transmitting acrylic resin (poly methyl methacrylate (PMMA)).

The housing 300 of the display unit 50 accommodates the liquid crystal display panel 100 and the backlight 200. The housing 300 has a box-like shape, as illustrated in FIGS. 5 and 6. The housing 300 is formed of resin or metal. The housing 300 includes a protrusion 310 extending from a side plate 330 into the housing 300, and the liquid crystal display panel 100 is disposed on the protrusion 310. Also, the backlight 200 is disposed on a bottom surface 320 of the housing 300.

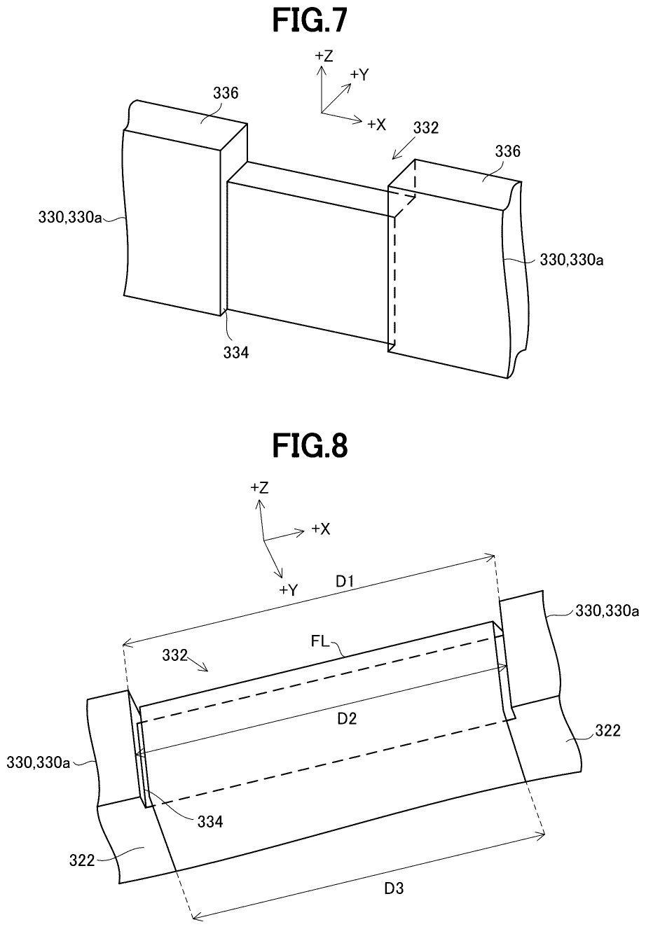

The housing 300 has the opening 332 to lead out the flexible substrate FL, which connects to the liquid crystal display panel 100, from the outside of the housing 300. As illustrated in FIGS. 6 and 7, the opening 332 is formed by cutting out an upper portion of the side plate 330 (hereinafter referred to as the side plate 330a) located on the side from which the flexible substrate FL is led out. The side plate 330a corresponds to the side plate 330 of the housing 300 having the opening 332. The side plate 330a may also be referred to as the side plate 330 of the housing 300 on the side where the flexible substrate FL is located.

Also, the side plate 330a has the groove 334. The flexible substrate FL led out from the opening 332 toward the outside of the housing 300 extends through the groove 334 of the side plate 330a to the bottom surface 322 of the housing 300, as illustrated in FIG. 8. The width D1 of the opening 332 (in the X direction) and the width D2 of the groove 334 are greater than the width D3 of the flexible substrate FL.

Returning to FIG. 2, the cover 400 of the display device 10 is disposed on the display surface 100a side (+Z side) of the liquid crystal display panel 100 and protect the display unit 50. The cover 400 is formed in a flat plate shape from a light-transmissive resin, glass, or the like. As illustrated in FIGS. 1 and 2, the outer dimensions (in the X and Y directions) of the cover 400 are larger than the outer dimensions (in the X and Y directions) of the display unit 50. Thus, in a cross-sectional view, the cover 400 extends outward from the outer dimensions of the display unit 50.

The cover 400 (the main surface 400a of the cover 400 on the liquid crystal display panel 100 side) is adhered to the upper surface 336 of the side plate 330 of the housing 300 by an adhesive member 410, as illustrated in FIG. 2. The adhesive member 410 is provided over the entire upper surface 336 of the side plate 330, except for a portion forming the opening 332 (FIG. 6). The adhesive member 410 may be an adhesive, a double-sided tape, or the like. The cover 400 and the liquid crystal display panel 100 are adhered together by a light-transmissive adhesive 420, such as an optical clear adhesive (OCA).

The waterproof film 500 of the display device 10 is formed into a rectangular sheet from a resin, such as a polyester resin, an acrylic resin, or an olefin-based resin. The waterproof film 500 is flexible and bendable. As illustrated in FIG. 9, the width D4 (length in the X direction) of the waterproof film 500 is greater than the width D1 of the opening 332, the width D2 of the groove 334, and the width D3 of the flexible substrate FL.

The waterproof film 500 covers a gap 502, including the opening 332, between the cover 400 and the side plate 330a of the housing 300, with the flexible substrate FL passing through the opening 332 of the side plate 330a of the housing 300. The gap 502 includes the opening 332, and the expression “the gap 502, including the opening 332, between the cover 400 and the side plate 330a of the housing 300” may also be referred to as “the gap 502 between the cover 400 and the side plate 330a of the housing 300”, or “the gap 502”.

Specifically, as illustrated in FIGS. 9 to 12, the waterproof film 500 covers the gap 502 such that the +Z side end portion of the waterproof film 500 is affixed to the main surface 400a of the cover 400 on the liquid crystal display panel 100 side and the waterproof film 500 is further affixed to the side plate 330 and the bottom surface 322 extending from the side plate 330a of the housing 300 to the bottom surface 322 of the housing 300. As illustrated in FIGS. 9 and 12, the waterproof film 500 also covers the flexible substrate FL, led out from the opening 332, from the side plate 330a of the housing 300 to the bottom surface 322 of the housing 300, and also covers the side plate 330a. The waterproof film 500 is affixed to the main surface 400a of the cover 400, the side plate 330a of the housing 300, and the bottom surface 322 of the housing 300 by an adhesive, the adhesive layer provided on the waterproof film 500, or the like. The waterproof film 500 is affixed to the side plate 330a of the housing 300 and the bottom surface 322 of the housing 300, straddling the flexible substrate FL.

In the present embodiment, the waterproof film 500 is affixed to the main surface 400a of the cover 400 on the liquid crystal display panel 100 side, the side plate 330a of the housing 300, and the bottom surface 322 of the housing 300, and covers the gap 502, including the opening 332, between the cover 400 and the side plate 330a of the housing 300, thereby allowing ingress of moisture through the gap 502 into the display device 10 to be suppressed. Since the ingress of moisture into the display device 10 can be suppressed, the display device 10 can exhibit high waterproof performance.

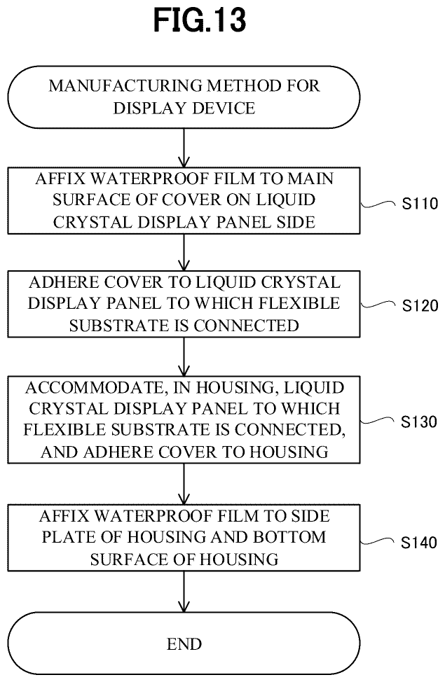

Next, a manufacturing method for the display device 10 is described. FIG. 13 is a flowchart illustrating the manufacturing method for the display device 10. The manufacturing method for the display device 10 includes a step of affixing the waterproof film 500 to the main surface 400a of the cover 400 on the liquid crystal display panel 100 side (step S110), a step of adhering the cover 400 to the liquid crystal display panel 100 to which the flexible substrate FL is connected (step S120), a step of accommodating, in the housing 300, the liquid crystal display panel 100 to which the flexible substrate FL is connected and adhering the cover 400 to the housing 300 (step S130), and affixing the waterproof film 500 to the side plate 330a of the housing 300 and the bottom surface 322 of the housing 300 (step S140).

In step S110, the end portion of the waterproof film 500 is affixed to the main surface 400a of the cover 400 on the liquid crystal display panel 100 side by the adhesive layer provided on the waterproof film 500.

In step S120, the cover 400 to which the waterproof film 500 is affixed is adhered by an adhesive 420 to the liquid crystal display panel 100 to which the flexible substrate FL is connected.

In step S130, first, the adhesive member 410 is provided on the upper surface 336 of the side plate 330, except for a portion, forming the opening 332, of the housing 300 in which the backlight 200 is accommodated. Next, the liquid crystal display panel 100 to which the flexible substrate FL is connected is accommodated in the housing 300, and the cover 400 (the main surface 400a) is adhered to the housing 300 (the upper surface 336 of the side plate 330). In conjunction with adhering of the cover 400 to the housing 300, the flexible substrate FL is led out to the outside of the housing 300 through the opening 332, routed via the groove 334, and extended to the bottom surface 322 of the housing 300. The flexible substrate FL is then fixed to the bottom surface 322.

In step S140, the waterproof film 500 is affixed to the side plate 330a of the housing 300 and the bottom surface 322 of the housing 300 by the adhesive layer provided on the waterproof film 500. Thus, the display device 10 can be manufactured.

In the manufacturing method for the display device 10 according to the present embodiment, the waterproof film 500 is pre-affixed to the cover 400, thereby facilitating the manufacturing of the display device 10. For example, when the frame region 112 of the liquid crystal display panel 100 is narrow, it is difficult to affix the waterproof film 500 to the cover 400 after adhering the cover 400 to the liquid crystal display panel 100 to which the flexible substrate FL is connected. In the present embodiment, since the waterproof film 500 is pre-affixed to the cover 400, the display device 10 can be easily manufactured even when the frame region 112 of the liquid crystal display panel 100 or the gap 502 is narrow.

As described above, the waterproof film 500 is affixed to the main surface 400a of the cover 400 on the liquid crystal display panel 100 side, the side plate 330a of the housing 300, and the bottom surface 322 of the housing 300, and covers the gap 502, including the opening 332, between the cover 400 and the side plate 330a of the housing 300. Thus, the display device 10 exhibits high waterproof performance.

### Embodiment 2

In Embodiment 1, the waterproof film 500 has a rectangular shape. The waterproof film 500 may include a cutout 510.

The configuration of the display device 10 in the present embodiment is the same as that of the display device 10 in Embodiment 1, except for the shape of the waterproof film 500. Here, the shape of the waterproof film 500 in the present embodiment and a relationship between the waterproof film 500 and the adhesive member 410 are mainly described.

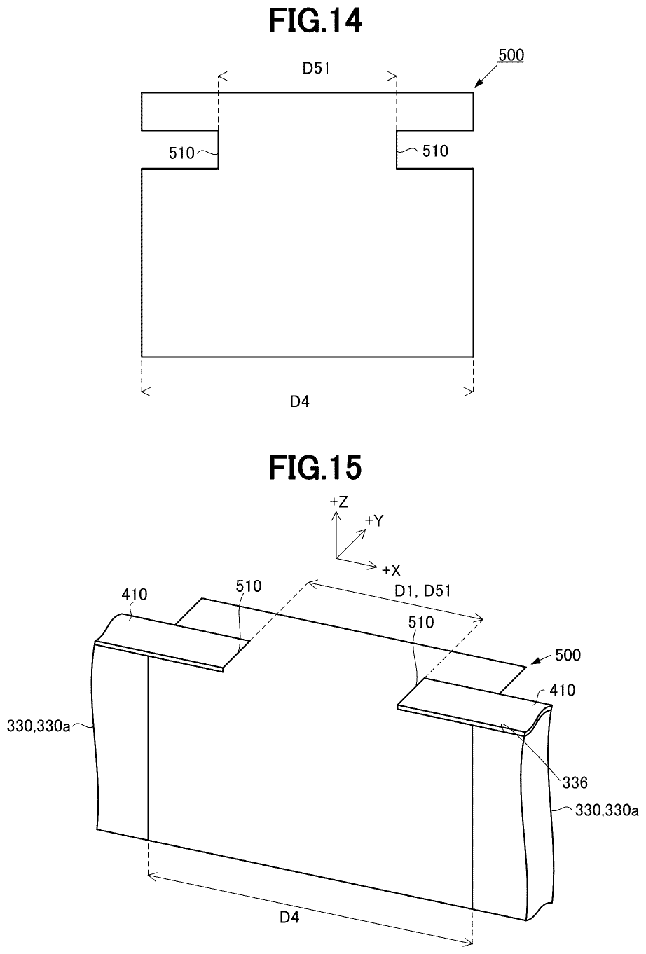

As illustrated in FIG. 14, the waterproof film 500 in the present embodiment includes the cutouts 510 on both sides. The distance D51 between the cutouts 510 is equal to the width D1 of the opening 332 in the housing 300. The cutouts 510 are provided to avoid the adhesive member 410 that adheres the cover 400 to the housing 300, when the waterproof film 500 is affixed to the main surface 400a of the cover 400 on the liquid crystal display panel 100 side, the side plate 330a of the housing 300, and the bottom surface 322 of the housing 300, as illustrated in FIG. 15. In FIG. 15, the waterproof film 500 is illustrated by solid lines to facilitate comprehension.

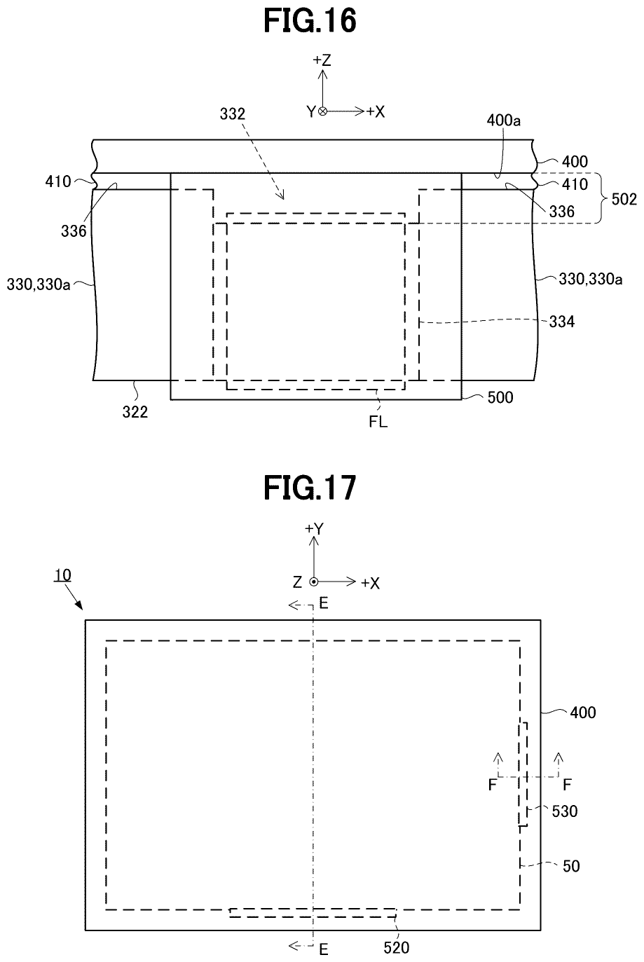

In the present embodiment, the waterproof film 500 is affixed to the main surface 400a of the cover 400, the side plate 330a of the housing 300, and the bottom surface 322 of the housing 300 while avoiding, by the cutouts 510, the adhesive member 410 that is provided on the upper surface 336 of the side plate 330a of the housing 300 and adheres the cover 400 to the housing 300. Thus, as illustrated in FIG. 16, the waterproof film 500 does not overlap with the adhesive member 410, allowing the thickness of the display device 10 to be reduced.

As described above, since the waterproof film 500 includes cutouts 510, the thickness of the display device 10 can be reduced. Furthermore, similarly to the display device 10 in Embodiment 1, the waterproof film 500 is affixed to the main surface 400a of the cover 400 on the liquid crystal display panel 100 side, the side plate 330a of the housing 300, and the bottom surface 322 of the housing 300, and covers the gap 502. Thus, the display device 10 of the present embodiment also exhibits high waterproof performance.

### Embodiment 3

In Embodiment 1, the display unit 50 includes the liquid crystal display panel 100, the flexible substrate FL, the backlight 200, and a housing 300. The display unit 50 may further include the touch panel 600.

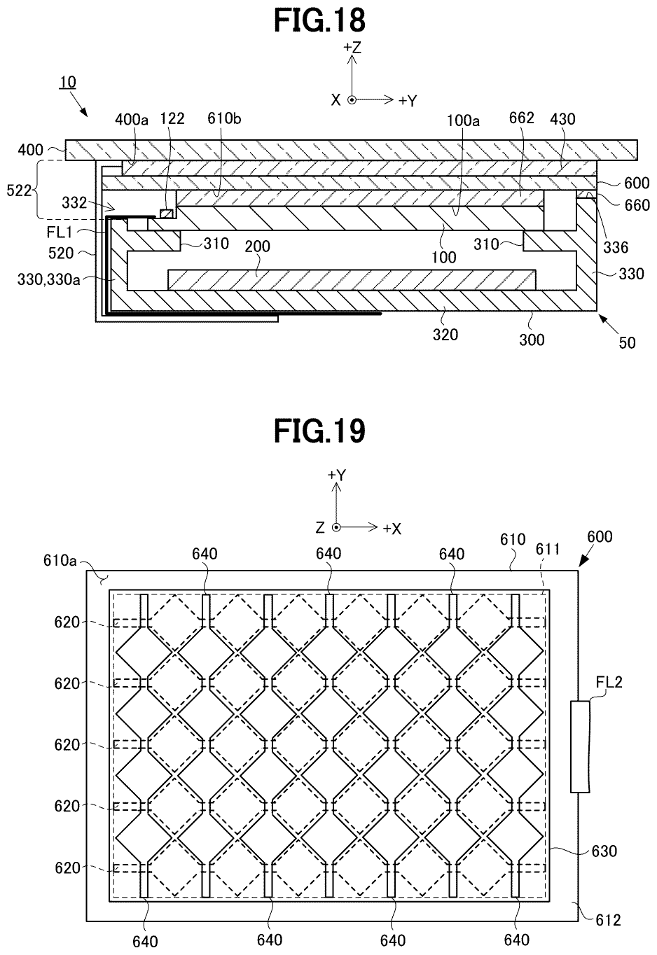

As illustrated in FIG. 17, the display device 10 of the present embodiment includes the display unit 50, the cover 400, a first waterproof film 520, and a second waterproof film 530. As illustrated in FIG. 18, the display unit 50 of the present embodiment includes the liquid crystal display panel 100, a first flexible substrate FL1, the backlight 200, the housing 300, and the touch panel 600. The display unit 50 of the present embodiment also includes a second flexible substrate FL2 described later.

Similarly to the display unit 50 of Embodiment 1, the display unit 50 of the present embodiment displays characters, images, and the like. In addition, the display unit 50 of the present embodiment receives user input via the touch panel 600.

The configuration of the liquid crystal display panel 100, the backlight 200, and the housing 300 in the display unit 50 of the present embodiment is the same as the configuration of the liquid crystal display panel 100, the backlight 200, and the housing 300 in Embodiment 1. The configuration of the first flexible substrate FL1 of the display unit 50 in the present embodiment is also the same as that of the flexible substrate FL in Embodiment 1. Here, the touch panel 600 and the second flexible substrate FL2 are described.

The touch panel 600 is a capacitive touch panel. As illustrated in FIG. 19, the touch panel 600 includes a light-transmissive substrate 610, a plurality of first electrodes 620, an insulating layer 630, and a plurality of second electrodes 640.

The light-transmissive substrate 610 is, for example, a glass substrate. The light-transmissive substrate 610 includes a first main surface 610a located on the +Z side. The light-transmissive substrate 610 also includes a detection region 611 and a frame region 612 surrounding the detection region 611. The detection region 611 corresponds to the display region 111 of the liquid crystal display panel 100.

The first electrodes 620 are provided on the first main surface 610a of the light-transmissive substrate 610. The first electrodes 620 extend in the X direction and are arranged at equal intervals in the Y direction. The first electrodes 620 has a pattern in which corners of multiple rectangles are connected in a row (so-called diamond pattern). Each of the first electrodes 620 is connected to the second flexible substrate FL2 via unillustrated wiring.

The insulating layer 630 is provided on the first electrodes 620, and insulates the first electrodes 620 from the second electrodes 640. The insulating layer 630 is, for example, a silicon oxide thin film.

The second electrodes 640 are provided on the insulating layer 630. The second electrodes 640 extend in the Y direction. Similarly to the first electrodes 620, the second electrodes 640 have a pattern in which multiple corners of rectangular shapes are connected in a row. Each of the second electrodes 640 is connected to the second flexible substrate FL2 via unillustrated wiring.

The first electrodes 620 and the second electrodes 640 are formed, for example, from indium tin oxide (ITO). When the touch panel 600 is viewed in plan, the first electrodes 620 and the second electrodes 640 intersect at connections where the corners of rectangles are connected. The first electrodes 620 and the second electrodes 640 form capacitance with a target (e.g., a user's finger, hand, pen, etc.)

When viewed in plan, the outer dimensions (in the X and Y directions) of the touch panel 600 (light-transmissive substrate 610) are the same as the outer dimensions of the housing 300. As illustrated in FIG. 18, the touch panel 600 is disposed on the display surface 100a side (+Z side) of the liquid crystal display panel 100, and a second main surface 610b, opposite to the first main surface 610a of the light-transmissive substrate 610, is adhered to the upper surface 336 of the side plate 330 of the housing 300 by an adhesive member 660. The adhesive member 660 is provided over the entire upper surface 336 of the side plate 330, except for a portion forming the opening 332, similarly to the adhesive member 410 of Embodiment 1. A light-transmissive adhesive 662 is filled between the touch panel 600 and the liquid crystal display panel 100. The second main surface 610b, opposite to the first main surface 610a of the light-transmissive substrate 610, corresponds to the main surface of the touch panel 600 on the liquid crystal display panel 100 side.

The second flexible substrate FL2 is connected to the first electrodes 620 and the second electrodes 640 of the touch panel 600, and connects the touch panel 600 to the outside. As illustrated in FIG. 19, the second flexible substrate FL2 is connected to the touch panel 600 (the first electrodes 620 and the second electrodes 640) via unillustrated wiring at an end portion of the frame region 612 located on the +X side.

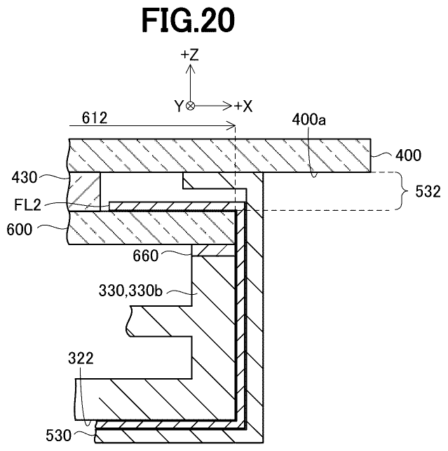

As illustrated in FIG. 20, the second flexible substrate FL2 extends from the end portion of the frame region 612 located on the +X side of the touch panel 600, along the side plate 330 (hereinafter referred to as the side plate 330b) of the housing 300 on the +X side, and further extends to the bottom surface 322 of the housing 300. In the present embodiment, the second flexible substrate FL2 is fixed to the bottom surface 322 of the housing 300 by an unillustrated adhesive member. The side plate 330b corresponds to the side plate 330 of the housing 300 on the side where the second flexible substrate FL2 is located.

Returning to FIG. 18, the cover 400 of the present embodiment is disposed on the display surface 100a side (+Z side) of the liquid crystal display panel 100 and covers the touch panel 600. The cover 400 of the present embodiment is adhered to the touch panel 600 by a light-transmissive adhesive 430. Specifically, the main surface 400a of the cover 400 on the liquid crystal display panel side is adhered to the touch panel 600. In the present embodiment, the second flexible substrate FL2 and a portion of the frame region 612 of the touch panel 600 around the second flexible substrate FL2 are not adhered to the main surface 400a of the cover 400. In addition, a portion of the main surface 400a of the cover 400 to which the first waterproof film 520 is affixed is not adhered to the touch panel 600.

In the present embodiment, since the second flexible substrate FL2 and the portion of the frame region 612 of the touch panel 600 around the second flexible substrate FL2 are not adhered to the cover 400, a gap 532 is formed between the cover 400 and the frame region 612 of the touch panel 600 to which the second flexible substrate FL2 is connected, as illustrated in FIG. 20. The other configuration of the cover 400 in the present embodiment is the same as that of the cover 400 in Embodiment 1.

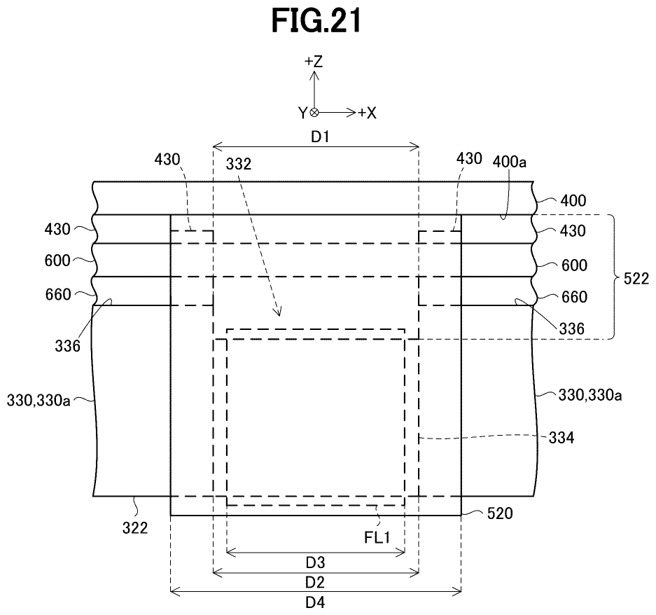

Similarly to the waterproof film 500 of Embodiment 1, the first waterproof film 520 of the display device 10 of the present embodiment is affixed to the main surface 400a of the cover 400 on the liquid crystal display panel 100 side, the side plate 330a of the housing 300, and the bottom surface 322 of the housing 300, and covers a gap 522, including the opening 332, between the cover 400 and the side plate 330a of the housing 300 (in FIGS. 18 and 21). Accordingly, the first waterproof film 520 can suppress the ingress of moisture into the display device 10 through the gap 522, similarly to the waterproof film 500 in Embodiment 1. The other configuration of the first waterproof film 520 is also the same as that of the waterproof film 500 in Embodiment 1.

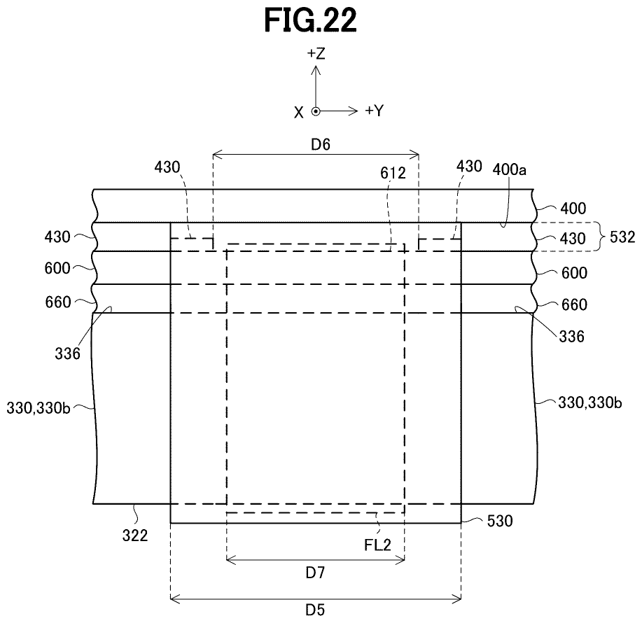

The second waterproof film 530 of the display device 10 of the present embodiment covers the gap 532 between the cover 400 and the frame region 612 of the touch panel 600 to which the second flexible substrate FL2 is connected. Specifically, as illustrated in FIGS. 20 and 22, the +Z−side end portion of the second waterproof film 530 is affixed to the main surface 400a of the cover 400 on the liquid crystal display panel 100 side, and the second waterproof film 530 is affixed to the side plate 330b of the housing 300 and the bottom surface 322 of the housing 300, extending from the side plate 330b to the bottom surface 322, thereby covering the gap 532. In addition, the second waterproof film 530 covers the second flexible substrate FL2 from the side plate 330b of the housing 300 to the bottom surface 322 of the housing 300, and also covers the side plate 330b. Similarly to the waterproof film 500 of Embodiment 1, the second waterproof film 530 is affixed to the main surface 400a of the cover 400, the side plate 330b of the housing 300, and the bottom surface 322 of the housing 300 by an adhesive, an adhesive layer provided on the second waterproof film 530, or the like. The second waterproof film 530 is affixed to the side plate 330b of the housing 300 and the bottom surface 322 of the housing 300, straddling the second flexible substrate FL2.

As illustrated in FIG. 22, the width D5 (length in the Y direction) of the second waterproof film 530 is greater than the width D6 of the gap 532. Further, the width D6 of the gap 532 is greater than the width D7 of the second flexible substrate FL2.

In the present embodiment, the second waterproof film 530 is affixed to the main surface 400a of the cover 400 on the liquid crystal display panel 100 side, the side plate 330b of the housing 300, and the bottom surface 322 of the housing 300, and covers the gap 532 between the cover 400 and the frame region 612 of the touch panel 600 to which the second flexible substrate FL2 is connected. Thus, the ingress of moisture into the display device 10 through the gap 532 can be suppressed.

As described above, the first waterproof film 520 suppresses the ingress of moisture through the gap 522, and the second waterproof film 530 suppresses the ingress of moisture through the gap 532. Thus, the display device 10 of the present embodiment can achieve high waterproof performance.

### Embodiment 4

In Embodiment 3, the first waterproof film 520 is affixed to the main surface 400a of the cover 400 on the liquid crystal display panel 100 side. The first waterproof film 520 may also be affixed to the touch panel 600.

The configuration of the display device 10 of the present embodiment is the same as that of the display device 10 in Embodiment 3, except for the affixing of the first waterproof film 520. Here, the affixing of the first waterproof film 520 of the present embodiment is described.

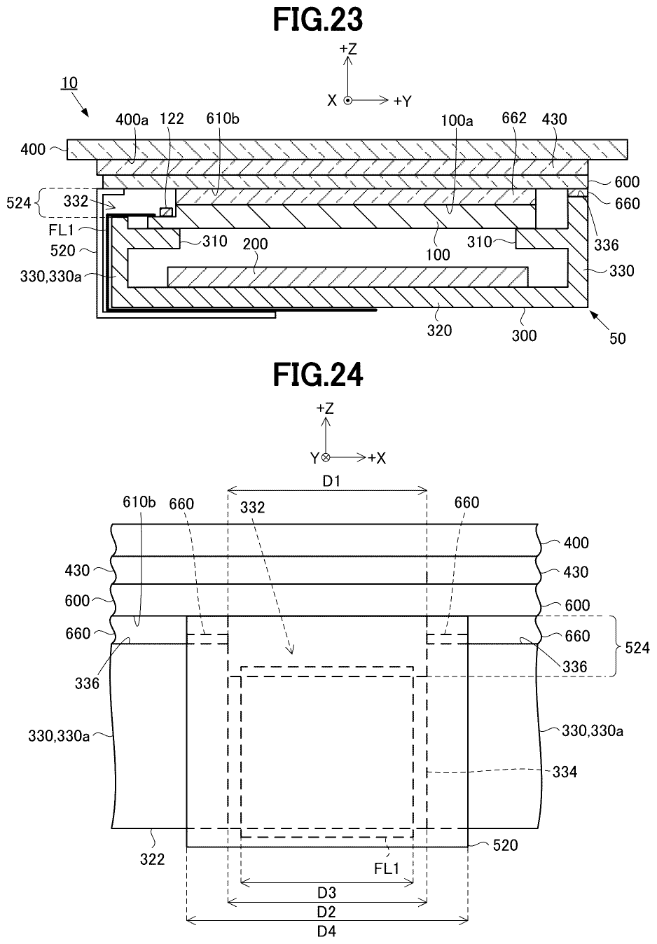

As illustrated in FIGS. 23 and 24, the first waterproof film 520 of the present embodiment is affixed to the main surface 610b of the touch panel 600 on the liquid crystal display panel 100 side (i.e., the second main surface opposite to the first main surface 610a of the light-transmissive substrate 610), the side plate 330a of the housing 300, and the bottom surface 322 of the housing 300, and covers a gap 524, including the opening 332, between the touch panel 600 and the side plate 330a of the housing 300. Thus, the ingress of moisture into the display device 10 through the gap 524 can be suppressed.

As described above, the first waterproof film 520 of the present embodiment can suppress the ingress of moisture through the gap 524. In addition, the second waterproof film 530, similarly to Embodiment 3, can suppress the ingress of moisture through the gap 532. Thus, the display device 10 of the present embodiment can also achieve high waterproof performance.

### Embodiment 5

In Embodiments 1 and 2, the waterproof film 500 is formed from resin. Likewise, in Embodiments 3 and 4, the first waterproof film 520 and the second waterproof film 530 are formed from resin. The waterproof film 500, the first waterproof film 520, and the second waterproof film 530 may be films containing metal.

The display device 10 of the present embodiment includes the display unit 50, the cover 400, and the waterproof film 500, similarly to the display device 10 in Embodiment 1. The configuration of the display device 10 of the present embodiment is the same as that of the display device 10 of Embodiment 1, except for the configuration of the housing 300 of the display unit 50 and the waterproof film 500.

The housing 300 of the present embodiment is formed from metal. For example, the housing 300 may be formed from an aluminum alloy by die casting. The other configuration of the housing 300 of the present embodiment is the same as that of the housing 300 of Embodiment 1.

The waterproof film 500 of the present embodiment is a film containing metal (e.g., aluminum or copper). Examples of such metal-containing films include films formed from resin containing metal particles, resin films with metal (e.g., aluminum or copper) vapor-deposited (metal-deposited films), and metal foils (e.g., aluminum foil or copper foil). The other configuration of the waterproof film 500 of the present embodiment is the same as that of the waterproof film 500 of Embodiment 1.

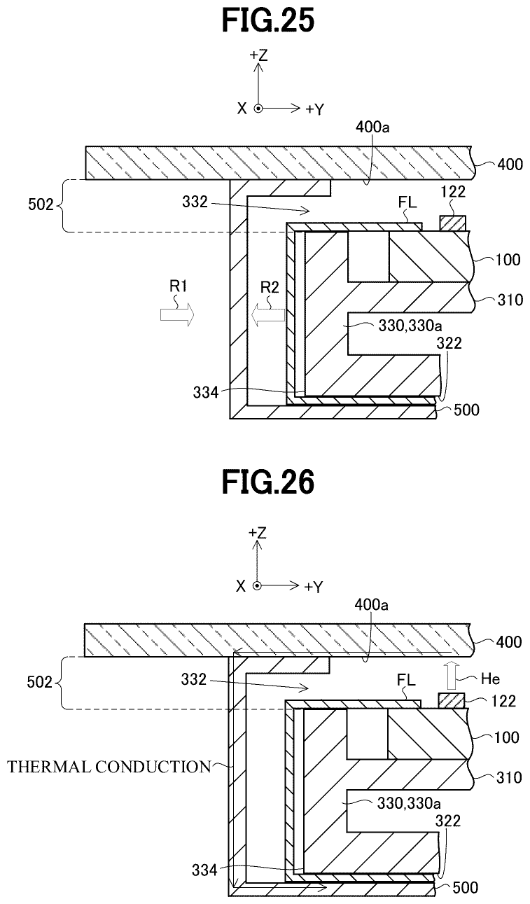

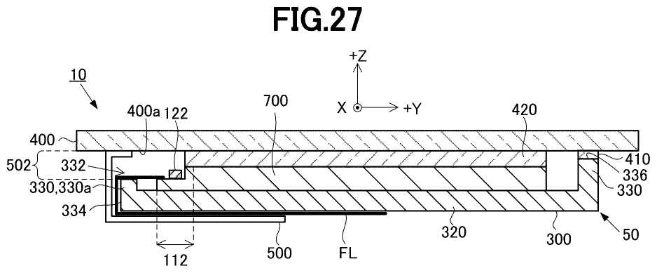

In the present embodiment, since the waterproof film 500 contains metal and is affixed to the main surface 400a of the cover 400 and to the side plate 330a and bottom surface 322 of the housing 300 formed from metal, the waterproof film 500 also functions as a shielding layer that absorbs or reflects electromagnetic waves. As a result, the waterproof film 500 of the present embodiment can block electromagnetic waves R1 radiated toward the display device 10 from the outside and suppress electromagnetic interference from the outside to the display device 10, as illustrated in FIG. 25. Furthermore, as illustrated in FIG. 25, the waterproof film 500 of the present embodiment can also suppress the leakage of electromagnetic waves R2 radiated from the flexible substrate FL of the display device 10 to the outside. Additionally, as illustrated in FIG. 26, the waterproof film 500 of the present embodiment can diffuse heat He emitted from the driver IC 122 to the housing 300 via thermal conduction, thereby suppressing the thermal impact on components constituting the display device 10.

As described above, the waterproof film 500 of the present embodiment can suppress electromagnetic interference. Moreover, the waterproof film 500 of the present embodiment can suppress the effects of heat generated by the driver IC 122. The display device 10 of the present embodiment also has high waterproof performance, similarly to the display device 10 of Embodiment 1.

### Modifications

The above-described embodiments may be modified in various manners within the gist of the present disclosure.

The display unit 50 includes a display panel for displaying characters, images, and the like, and the flexible substrate FL or the first flexible substrate FL1 only needs to be connected to the display panel.

For example, as illustrated in FIG. 27, the display unit 50 may include an organic electro luminescence (EL) display panel 700. In the example illustrated in FIG. 27, the flexible substrate FL is connected to the organic EL display panel 700 (driver IC 122) and connects the organic EL display panel 700 to the outside. The housing 300 accommodates the organic EL display panel 700.

In Embodiment 2, the distance D51 between one cutout 510 and the other cutout 510 may be approximately equal to the width D1 of the opening 332 of the housing 300.

In the embodiment, the cover 400 protects the display unit 50. The cover 400 may also serve as a component that provides a design feature to the user.

The first waterproof film 520 may include a cutout 510, similarly to the waterproof film 500 in Embodiment 2.

At least one of the first waterproof film 520 and the second waterproof film 530 in Embodiments 3 and 4 may be a film containing metal, similarly to the waterproof film 500 in Embodiment 5. By using a metal-containing film for at least one of the first waterproof film 520 or the second waterproof film 530, electromagnetic interference can be suppressed, and the effects of heat generated by the driver IC 122 can also be mitigated. When at least one of the first waterproof film 520 and the second waterproof film 530 is a metal-containing film, the housing 300 is preferably formed from metal.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

1. A display device comprising:
a display panel;
a flexible substrate that connects to the display panel and connects the display panel to an outside;
a housing that accommodates the display panel and has an opening in a side plate through which the flexible substrate passes;
a cover that is disposed on a display surface side of the display panel and adhered to the housing; and
a waterproof film that is affixed to a main surface of the cover on a display panel side thereof, the side plate of the housing having the opening, and a bottom surface of the housing, and covering a gap, including the opening, between the cover and the side plate of the housing having the opening, with the flexible substrate passing through the opening.

2. The display device according to claim 1, wherein
the waterproof film includes a cutout that avoids an adhesive member that adheres the cover to the housing.

3. The display device according to claim 1, wherein
the waterproof film is a film including metal.

4. A display device comprising:
a display panel;
a first flexible substrate that connects to the display panel and connect the display panel to an outside;
a housing that accommodates the display panel and has an opening in a side plate through which the first flexible substrate passes;
a touch panel that is disposed on a display surface side of the display panel and adhered to the housing;
a second flexible substrate that connects to a frame region of the touch panel and connects the touch panel to the outside;
a cover that covers the touch panel and is adhered to the touch panel;
a first waterproof film that is affixed to a main surface of the cover on a display panel side thereof, the side plate of the housing having the opening, and a bottom surface of the housing, and covers a gap, including the opening, between the cover and the side plate of the housing having the opening, with the first flexible substrate passing through the opening; and
a second waterproof film that is affixed to the main surface of the cover on the display panel side, the side plate of the housing, and the bottom surface of the housing, and covers a gap between the cover and the frame region of the touch panel to which the second flexible substrate is connected.

5. A display device comprising:
a display panel;
a first flexible substrate that connects to the display panel and connect the display panel to an outside;
a housing that accommodates the display panel and has an opening in a side plate through which the first flexible substrate passes;
a touch panel that is disposed on a display surface side of the display panel and adhered to the housing;
a second flexible substrate that connects to a frame region of the touch panel and connects the touch panel to the outside;
a cover that covers the touch panel and is adhered to the touch panel;
a first waterproof film that is affixed to a main surface of the touch panel on a display panel side thereof, the side plate of the housing having the opening, and a bottom surface of the housing, and covers a gap, including the opening, between the touch panel and the side plate of the housing having the opening, with the first flexible substrate passing through the opening; and
a second waterproof film that is affixed to a main surface of the cover on a display panel side thereof, the side plate of the housing, and the bottom surface of the housing, and covering a gap between the cover and the frame region of the touch panel to which the second flexible substrate is connected.

6. The display device according to claim 4, wherein
the first waterproof film includes a cutout that avoids an adhesive member that adheres the touch panel to the housing.

7. The display device according to claim 4, wherein
at least one of the first waterproof film or the second waterproof film is a film including metal.
